(19) United States
(12) Patent Application Publication
(10) Pub. No.: US 2009/0267180 A1
(43) Pub. Date: Oct. 29, 2009

(54) SEMICONDUCTOR DEVICE HAVING A REDUCED FUSE THICKNESS AND METHOD FOR MANUFACTURING THE SAME

(76) Inventor: Jun Ki KIM, Seoul (KR)

Correspondence Address: LADAS & PARRY LLP, 224 SOUTH MICHIGAN AVENUE, SUITE 1600, CHICAGO, IL, 60604, US

(21) Appl. No.: 12/245,318

(22) Filed: Oct. 3, 2008

(30) Foreign Application Priority Data
Apr. 28, 2008 (KR) 10-2008-0039521

(51) Int. Cl. H01L 21/768; H01L 23/525

(52) U.S. Cl. 257/529; 438/601; 257/E23.149; 257/E21.592

(57) ABSTRACT

A semiconductor device that has a reduced fuse thickness without compromising the bondability of an associated pad and a method for manufacturing the same is described. The semiconductor device includes a pad and a fuse formed on a planar level. The pad and fuse are formed using a metal according to the metal used for the planar level on which the pad and fuse are formed. The pad is formed such that the center portion of the pad is positioned lower than that of the fuse. During the opening of the pad, the thickness of the fuse is reduced without reducing the thickness of the pad. A subsequent repair process can then be easily performed on the fuse having the reduced thickness without degrading the bondability of the pad.

### CROSS-REFERENCE TO RELATED APPLICATIONS

The present application claims priority to Korean patent application number 10-2008-0039521 filed on Apr. 28, 2008, which is incorporated herein by reference in its entirety.

### BACKGROUND OF THE INVENTION

The present invention relates to a semiconductor device and a method for manufacturing the same, and more particularly, to a semiconductor device that can reduce the thickness of a fuse without degrading the bondability of a pad when forming the pad and the fuse using aluminum formed at the same level and a method for manufacturing the same.

In a memory device such as DRAM (dynamic random access memory), a large number of memory cells are integrated into one chip. If a defect occurs in even one of these memory cells, the reliability of the corresponding memory chip's information storing ability is deteriorated and loses its value as a finished product. In this regard, if the entire memory chip is classified as a defective product because a defect occurs in only one of the numerous memory cells, the manufacturing yield markedly decreases. Specifically, when considering the tendency towards integrating an increased number of memory cells in a chip of limited size to accommodate the high integration trend for a semiconductor device, the number of memory chips classified as defective products will increase. As a result, it may be impossible to manufacture a semiconductor memory device with economic efficiency.

In order to cope with this problem, a memory device is formed with auxiliary storage spaces called redundancies. The redundancies are located beside main cells and are inspected together with the main cells in a test mode so that a defective cell can be replaced with a redundancy if needed. This process is called a repair process. The repair process is conducted by cutting a wiring line that connects the main cell with the outside, i.e., a fuse, to prevent data from being inputted to a defective memory cell.

The metallic material used in the semiconductor manufacturing process is also used as the material for the fuse. Recently, in the semiconductor manufacturing process, copper (Cu) tends to be used as a wiring metal. This is due to copper having a low resistance and a high melting point when compared to aluminum (Al), which had been used as a wiring metal previously, and is therefore suitable for a semiconductor device that operates at high speeds with low power consumption and having improved reliability.

However, when using copper as the material for the fuse, it is not easily cut during the repair process causing a technical problem. Cracks are also likely to occur in an insulation layer due to an increase in the volume of copper due to oxidation since copper is easily oxidized. Hence, even when copper is used to form a main wiring layer in the semiconductor manufacturing process, a single layer of aluminum needs to be formed and used as the material of the fuse.

FIG. 1 is a sectional view showing a pad part and a fuse part of a conventional semiconductor device. Referring to FIG. 1, in the conventional semiconductor device, a single layer of aluminum is used as the material for a wiring layer in addition to copper. The aluminum is used as the material for a pad and of a fuse formed at the same level.

In FIG. 1, the reference numeral 106a designates a first copper line, 106b a copper pattern, 110a and 110b contact plugs, 112a an aluminum line, 112b and 112c first and second aluminum patterns, 118 a second copper line, and 130b and 130c a pad and a fuse.

FIG. 2 is a plan view illustrating the pad part shown in FIG. 1. Referring to FIG. 2, the pad 130b includes the copper pattern 106b which has the shape of a quadrangular flat plate, the first aluminum pattern 112b located on the copper pattern 106b and also has the shape of a quadrangular flat plate, and a plurality of contact plugs 110b formed adjacent to the edges of the copper pattern 106b between the copper pattern 106b and the first aluminum pattern 112b.

In the semiconductor device having the pad part and the fuse part structured as described above and when considering the bondability thereof, it is advantageous that the metal layer of the pad part has a thickness greater than a predetermined thickness, for example, 4,000Å. Conversely, when considering the repair process, it is advantageous that the metal layer of the fuse part has a thickness that is as small as possible, for example, 2,000Å.

When opening the pad and the fuse formed at the same level, if the pad part and the fuse part are simultaneously etched as shown in FIG. 3A to reduce the thickness of the aluminum fuse 112c in consideration of the repair process, the bondability of the pad is likely to be degraded since the thickness of the first aluminum pattern 112b of the pad part is also reduced.

In order to overcome this problem, a masking and etching process may be conducted for each of the pad part and the fuse part as shown in FIG. 3B so that the pad part and the fuse part are opened separately from each other. Nevertheless, in this case, productivity deteriorates due to the addition of another process.

### SUMMARY OF THE INVENTION

The embodiments of the present invention are directed to a semiconductor device which can reduce the thickness of a fuse part without degrading the bondability of a pad, and a method for manufacturing the same.

The embodiments of the present invention are also directed to a semiconductor device which can adjust the thickness of a metal layer in a pad part and a fuse part without deteriorating productivity, and a method for manufacturing the same.

In one aspect of the present invention, a semiconductor device has a pad and a fuse which are formed using a metal of the same level, wherein a center portion of the pad is positioned lower than the fuse.

The pad and the fuse have a single-layered structure of aluminum or a multi-layered structure containing aluminum. For example, the pad and the fuse have a structure in which an aluminum layer is interposed between titanium-based metal layers.

The fuse has the shape of a flat plate.

In another aspect of the present invention, a semiconductor device comprises a first insulation layer; a first metal pattern formed in the first insulation layer and having a center portion in which the first insulation layer is filled; a second insulation layer formed on the first metal pattern and the first insulation layer and partially removed on a portion of the first insulation layer which is filled in the center portion of the first metal pattern; contact plugs formed in the second insulation layer on the first metal pattern; a second metal pattern formed on the contact plugs and in a partially removed portion of the second insulation layer to constitute a pad in cooperation with the first metal pattern and the contact plugs, and having a sectional shape which has a high peripheral portion and a low center portion; and a fuse composed of a third metal pattern which is formed on the second insulation layer separately from the pad to be positioned higher than the center portion of the second metal pattern.

A surface of the portion of the first insulation layer, which is filled in the center portion of the first metal pattern, is recessed. For example, the portion of the first insulation layer, which is filled in the center portion of the first metal pattern, is recessed by a depth of 200˜1,000Å.

The first metal pattern contains copper.

The second and third metal patterns have a single-layered structure of aluminum or a multi-layered structure containing aluminum. For example, the second and third metal patterns have a structure in which an aluminum layer is interposed between titanium-based metal layers.

The fuse has the shape of a flat plate.

In another aspect of the present invention, a semiconductor device comprises a first insulation layer; a second insulation layer formed on the first insulation layer, wherein a portion of the second insulation layer is removed; a second metal pattern formed in the removed portion of the second insulation layer and on a portion of the second insulation layer adjacent to the removed portion, and having a longitudinal sectional shape which has a raised peripheral portion and a lowered center portion; a fuse composed of a third metal pattern formed on the second insulation layer separately from the second metal pattern to be positioned higher than the center portion of the second metal pattern; a third insulation layer formed on the second insulation layer including the second metal pattern and the fuse; contact plugs formed in the third insulation layer to contact the peripheral portion of the second metal pattern; and a first metal pattern formed on the third insulation layer including the contact plugs to form a pad in conjunction with the second metal pattern and the contact plugs, wherein a center portion of the first metal pattern is removed.

The second and third metal patterns are formed to have a single-layered structure of aluminum or a multi-layered structure containing aluminum.

The first metal pattern is formed of copper.

In another aspect of the present invention, a method for manufacturing a semiconductor device includes the step of forming a pad and a fuse using a metal of the same level, wherein the pad is formed such that a center portion thereof is positioned lower than the fuse.

The pad and the fuse are formed to have a single-layered structure of aluminum or a multi-layered structure containing aluminum. For example, the pad and the fuse are formed to have a structure in which an aluminum layer is interposed between titanium-based metal layers.

The fuse is formed to have the shape of a flat plate.

In still another aspect of the present invention, a method for manufacturing a semiconductor device comprises the steps of forming an interlayer dielectric on a semiconductor substrate which includes a pad part and a fuse part; forming a first insulation layer on the interlayer dielectric; forming a first metal pattern in the first insulation layer of the pad part such that the first metal pattern has a center portion in which the first insulation layer is filled; forming a second insulation layer on the first metal pattern and the first insulation layer; etching the second insulation layer, thereby removing a portion of the second insulation layer which is placed on a portion of the first insulation layer filled in the center portion of the first metal pattern and defining contact holes to expose the first metal pattern; forming contact plugs in the contact holes; forming a second metal pattern on the contact plugs of the pad part and in the removed portion of the second insulation layer such that the second metal pattern has a sectional shape which has a high peripheral portion and a low center portion, thereby constituting a pad which is composed of the first metal pattern, the contact plugs and the second metal pattern, and forming a fuse on the second insulation layer of the fuse part such that the fuse is composed of a third metal pattern and is positioned higher than the center portion of the second metal pattern; and forming a third insulation layer on the second insulation layer to cover the pad and the fuse.

The first metal pattern contains copper.

After the step of removing the portion of the second insulation layer which is placed on the portion of the first insulation layer filled in the center portion of the first metal pattern, the method further comprises the step of recessing the portion of the first insulation layer. Preferably, the portion of the first insulation layer is recessed by a depth of 200˜1,000Å.

The second and third metal patterns are formed to have a single-layered structure of aluminum or a multi-layered structure containing aluminum. For example, the second and third metal patterns are formed to have a structure in which an aluminum layer is interposed between titanium-based metal layers.

The fuse is formed to have the shape of a flat plate.

In still a further aspect of the present invention, a method for manufacturing a semiconductor device comprises the steps of forming an interlayer dielectric on a semiconductor substrate including a pad part and a fuse part; forming a first insulation layer on the interlayer dielectric; forming a second insulation layer on the first insulation layer; removing a portion of the second insulation layer in the pad part; forming a second metal pattern in the removed portion of the second insulation layer and on a portion of the second insulation layer adjacent to the removed portion to have a longitudinal sectional shape which has a raised peripheral portion and a lowered center portion, and at the same time, forming a fuse, composed of a third metal pattern, on the second insulation layer in the fuse part to be positioned higher than the center portion of the second metal pattern; forming a third insulation layer on the second insulation layer to cover the second metal pattern and the fuse; forming contact plugs in the third insulation layer on the peripheral portion of the second metal pattern; and forming a first metal pattern on the third insulation layer including the contact plugs to form a pad in conjunction with the second metal pattern and the contact plugs, wherein a center portion of the first metal pattern is removed.

The second and third metal patterns are formed to have a single-layered structure of aluminum or a multi-layered structure containing aluminum.

The first metal pattern is formed of copper.

The fuse is formed having a flat planar shape.

### BRIEF DESCRIPTION OF THE DRAWINGS

FIG. 1 is a sectional view showing a pad part and a fuse part of a conventional semiconductor device.

FIG. 2 is a plan view showing the pad part of a conventional semiconductor device shown in FIG. 1.

FIGS. 3A and 3B are sectional views illustrating the problems caused in the conventional art.

FIG. 4 is a sectional view showing a semiconductor device in accordance with one embodiment of the present invention.

FIG. 5 is a plan view showing the pad part shown in FIG. 4.

FIG. 6 is a sectional view showing a semiconductor device in accordance with another embodiment of the present invention.

FIGS. 7A through 7D are sectional views showing the processes of a method for manufacturing a semiconductor device in accordance with another embodiment of the present invention.

FIGS. 8A and 8B are sectional views showing a method for manufacturing a semiconductor device in accordance with another embodiment of the present invention.

FIGS. 9A and 9B are sectional views showing a method for manufacturing a semiconductor device in accordance with still another embodiment of the present invention.

FIG. 10 is a sectional view showing a semiconductor device in accordance with still a further embodiment of the present invention.

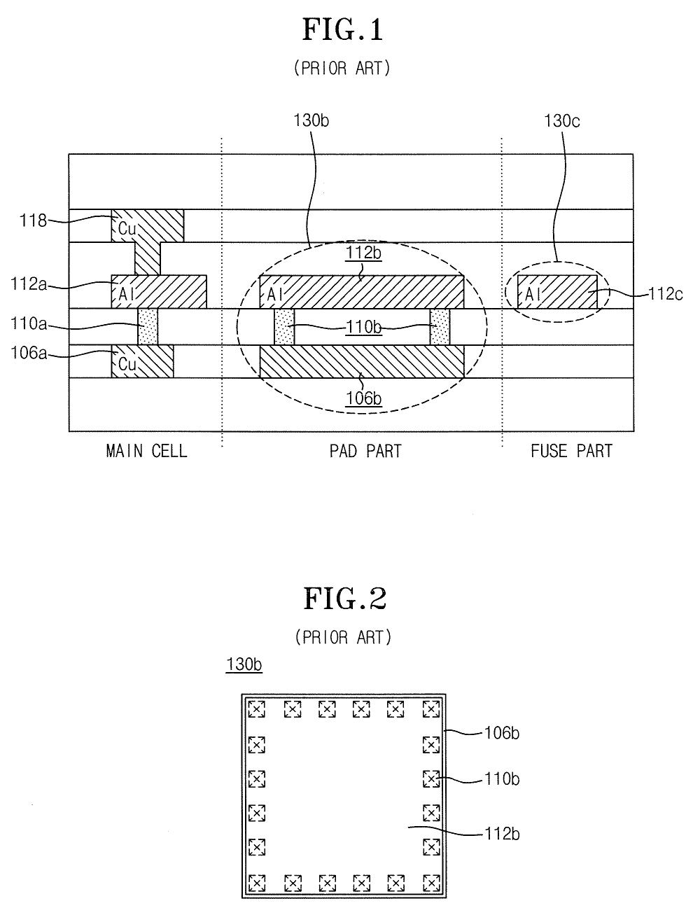

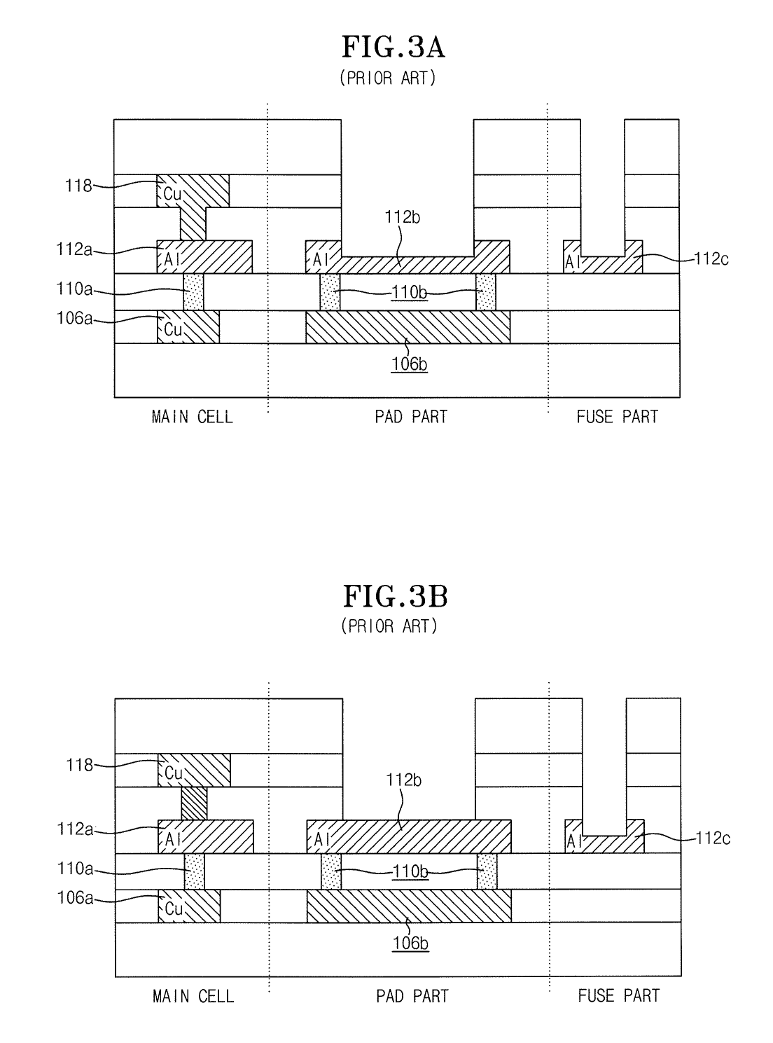

### DESCRIPTION OF SPECIFIC EMBODIMENTS

Hereafter, specific embodiments of the present invention will be described in detail with reference to the attached drawings.

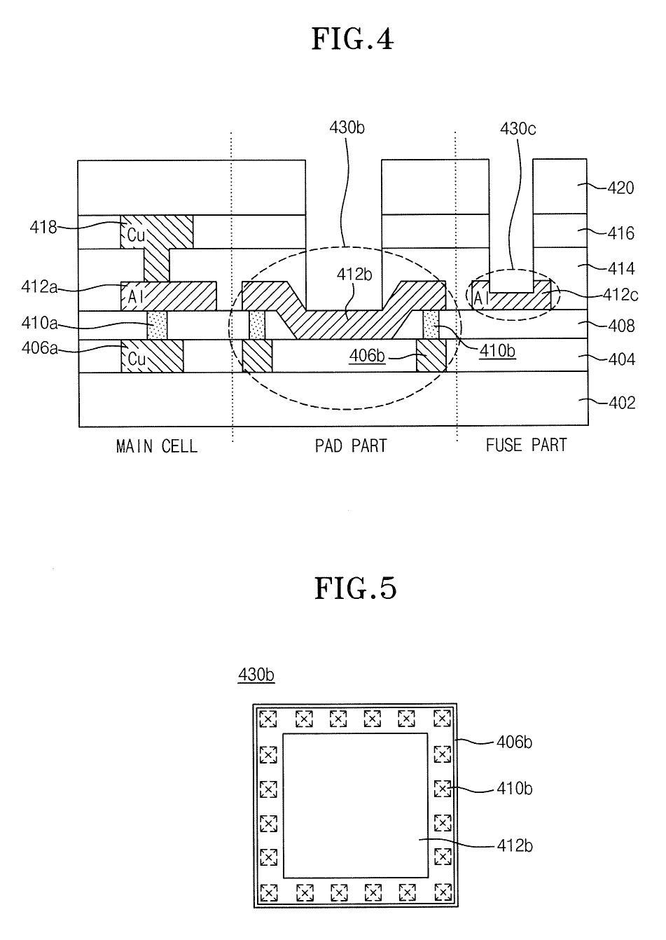

FIG. 4 is a sectional view showing a pad part and a fuse part of a semiconductor device in accordance with one embodiment of the present invention. FIG. 5 is a plan view showing the pad part shown in FIG. 4.

Referring to FIGS. 4 and 5, a semiconductor device according to one embodiment of the present invention includes a main cell, a pad part, and a fuse part. In the main cell, a first metal line 406a made of copper (Cu), a second metal line 412a including first contact plugs 410a made of aluminum (Al), and a third metal line 418 made of copper are formed in first through fourth insulation layers 404, 408, 414 and 416.

In the pad part, a pad 430b is formed. The pad 430b includes a first metal pattern 406b having a quadrangular transverse sectional shape made of copper, second contact plugs 410b formed on the first metal pattern 406b, and a second metal pattern 412b made of aluminum formed to contact the second contact plugs 410b and having a longitudinal sectional shape which has a raised peripheral portion and a lowered center portion.

More specifically, the first metal pattern 406b is formed in the first insulation layer 404 to have the transverse sectional shape of a picture frame which is formed by removing a center portion and leaving a peripheral portion in a flat plate. The first metal pattern 406b is formed of copper at the same level as the first metal line 406a of the main cell. The second contact plugs 410b are formed simultaneously with the first contact plugs 410a. The first contact plugs 410a electrically connect the first metal line 406a and the second metal line 412a of the main cell. The second contact plugs 410b are formed in the second insulation layer 408 on the first metal pattern 406b. The second metal pattern 412b is formed on the second insulation layer 408 including the second contact plugs 410b and in the second insulation layer 408 between the second contact plugs 410b such that it has the sectional shape having the raised peripheral portion and the lowered center portion. The second metal pattern 412b is formed from a metal used at the level upon which the second metal line 412a of the main cell is formed, i.e., aluminum.

In the fuse part, a fuse 430c is composed of a third metal pattern 412c formed in the shape of a flat plate on the second insulation layer 408 adjacent to the pad part. The third metal pattern 412c is formed simultaneously with the second metal pattern 412b of the pad part from a metal used at the level upon which the second metal pattern 412b is formed, i.e., aluminum. In particular, the third metal pattern 412c is formed in a position higher than the center portion of the second metal pattern 412b. The reference numeral 402 designates an interlayer dielectric, and the reference numeral 420 designates a fifth insulation layer.

Therefore, in the semiconductor device according to the present invention, the center portion of the second metal pattern constituting the pad is positioned lower than the third metal pattern constituting the fuse when forming the pad and the fuse using aluminum at the same level. Accordingly, the third metal pattern of the fuse part is exposed earlier than the second metal pattern of the pad part when conducting a repair etching process. As a result, even though etching is conducted to reduce the thickness of the third metal pattern of the fuse part, the second metal pattern of the pad part can maintain a thickness sufficient enough for bonding.

Thus, in the present invention, the laser cutting of the fuse part can be easily performed while maintaining the bondability of the pad part when forming the pad and the fuse using aluminum because a sufficient thickness of aluminum can be maintained in the pad part while still reducing the thickness of aluminum in the fuse part. As a result, the reliability of a semiconductor device can be improved.

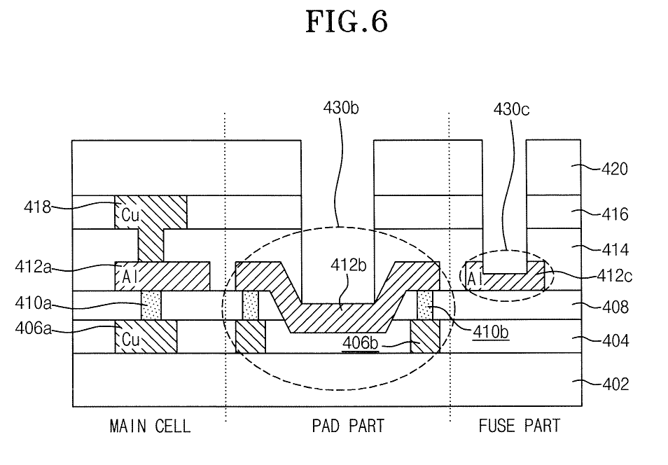

FIG. 6 is a sectional view showing a semiconductor device in accordance with a second embodiment of the present invention. Referring to FIG. 6, in the semiconductor device according to the second embodiment of the present invention, a portion of the surface of first insulation layer 404 formed between the first metal pattern 406b is recessed by a predetermined thickness, for example, 200˜1,000Å, when the overall thickness of the first insulation layer 404 is 2,000˜5,000Å. Therefore, the height of the center portion of the second metal pattern 412b constituting the pad 430b further decreases to be lower than the third metal pattern 412c constituting the fuse 430c.

Accordingly, in the semiconductor device according to the second embodiment of the present invention, the bondability of the pad can be even further improved while further reducing the thickness of the fuse when opening the pad and the fuse since the pad is opened later than that of the first embodiment.

Meanwhile, although a single-layered structure of aluminum is used in the aforementioned embodiments as the material for the second and third metal patterns respectively constituting the pad and the fuse, it is conceivable that a multi-layered structure containing aluminum can be used as the material of the second and third metal patterns. For example, a structure having an aluminum layer interposed between titanium-based metal layers, such as a Ti layer and a TiN layer, can be used as the material of the second and third metal patterns.

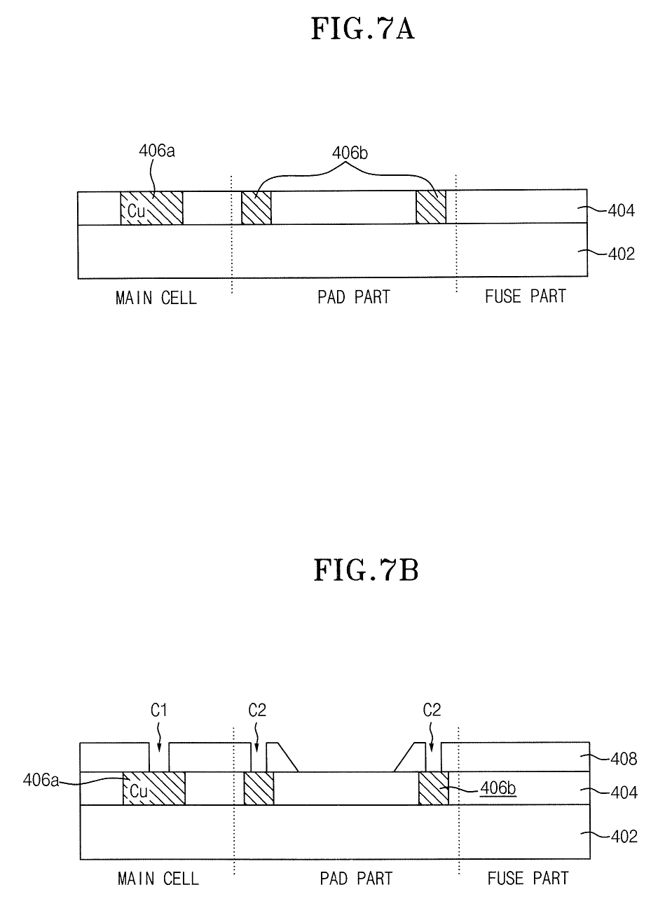

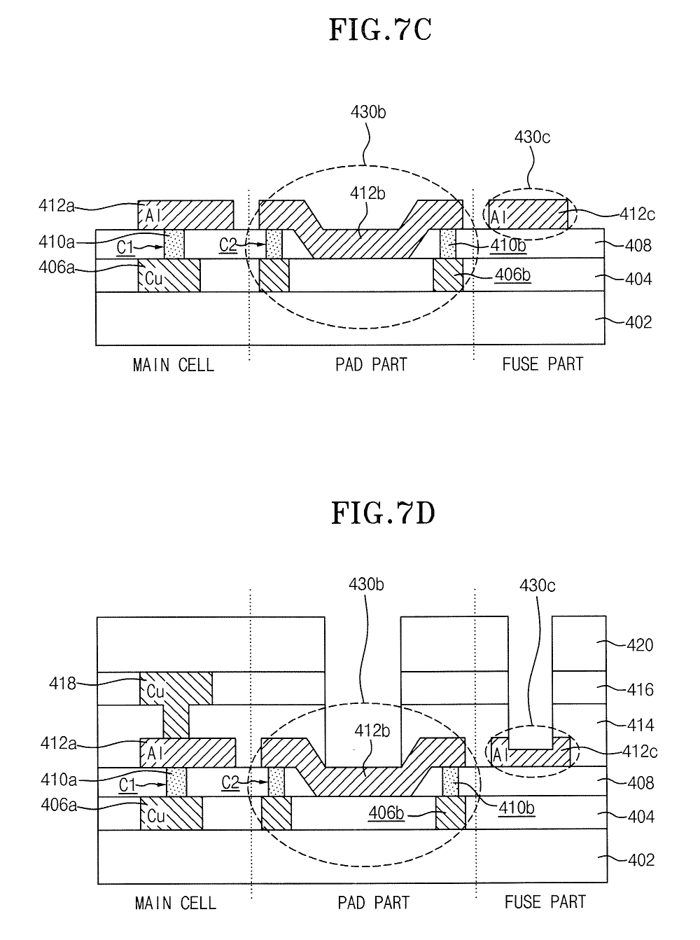

FIGS. 7A through 7D are sectional views showing the processes of a method for manufacturing a semiconductor device in accordance with a third embodiment of the present invention. The method will be described below with reference to FIGS. 7A through 7D.

Referring to FIG. 7A, an interlayer dielectric 402 is formed on the entire surface of a semiconductor substrate (not shown) which is divided into a main cell, a pad part, and a fuse part. It is understood that a lower structure including capacitors is formed in the main cell of the semiconductor substrate. A first insulation layer 404 is formed on the interlayer dielectric 402 and a first metal line 406a is formed in the main cell according to a well-known damascene process using copper. A first metal pattern 406b is also formed in the pad part using copper having the sectional shape of a picture frame produced by removing a center portion of the first metal pattern 406b and leaving the peripheral portion in a flat plate.

Referring to FIG. 7B, a second insulation layer 408 is formed on the first insulation layer 404 including the first metal line 406a and the first metal pattern 406b. Then, contact holes C1 and C2 are defined to expose the first metal line 406a of the main cell and the first metal pattern 406b of the pad part by etching the second insulation layer 408. At the same time, a portion of the second insulation layer 408 formed on the first insulation layer 404 located inside the first metal pattern 406b is removed.

While not shown in the drawings, a portion of the first insulation layer 404 exposed due to the removal of the second insulation layer 408 in the previous step, i.e., the portion of the first insulation layer 404 located between the first metal pattern 406b, can be additionally etched by a partial thickness, for example, 200˜1,000Å when the overall thickness of the first insulation layer 404 is 2,000˜5,000Å. The additional etching forms a recess in the portion of the first insulation layer 404 located between the first metal pattern 406b.

Referring to FIG. 7C, first contact plugs 410a and second contact plugs 410b are formed to respectively contact the first metal line 406a and the first metal pattern 406b, by filling a conductive layer in the contact holes C1 and C2. Thereafter, aluminum is deposited in the removed portion of the second insulation layer 408 and on the second insulation layer 408 including the first and second contact plugs 410a and 410b. Through patterning the aluminum, a second metal line 412a is formed in the main cell to contact the first contact plugs 410a, a second metal pattern 412b is formed in the pad part to contact the second contact plugs 410b, and a third metal pattern 412c is formed in the fuse part. Accordingly, a pad 430b composed of the first metal pattern 406b, the second contact plugs 410b, and the second metal pattern 412b is formed in the pad part. Additionally, a fuse 430c composed of the third metal pattern 412c is formed in the fuse part.

The third metal pattern 412c of the fuse part has the shape of a quadrangular flat plate. The second metal pattern 412b of the pad part has a longitudinal sectional shape having the raised peripheral portion and lowered center portion due to the removal of the second insulation layer 408 on the portion of the first insulation layer 404 located between the first metal pattern 406b. As a result, the center portion of the second metal pattern 412b of the pad part is positioned lower than the third metal pattern 412c of the fuse part.

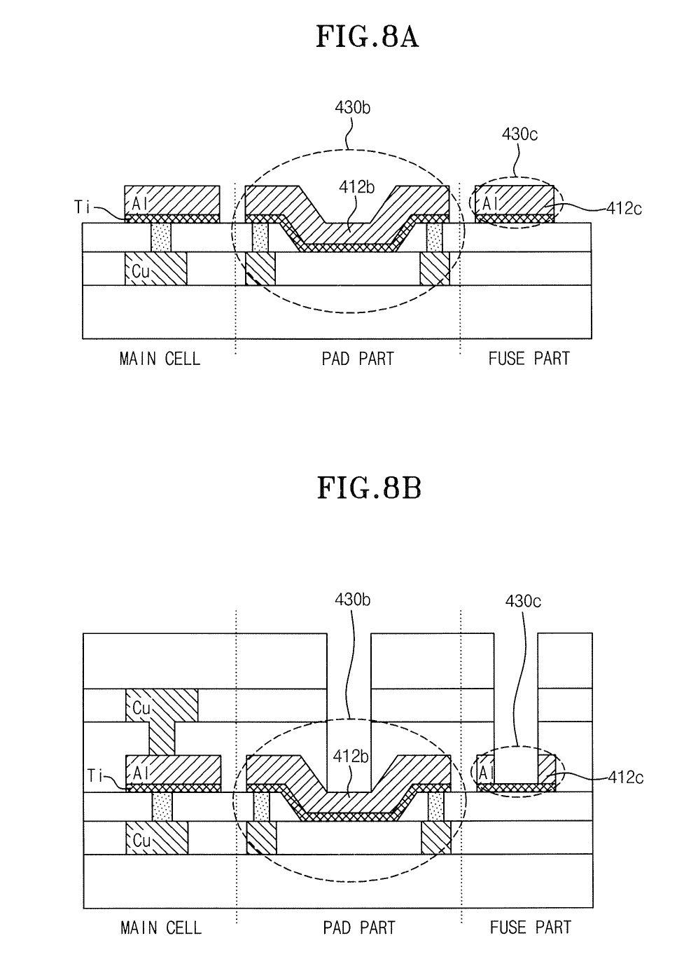

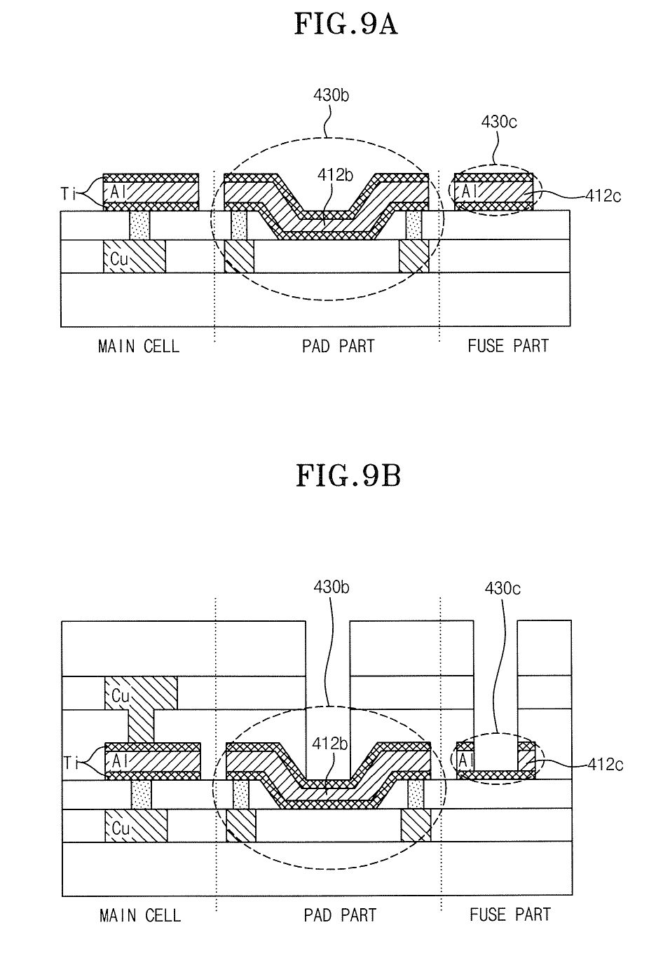

Although it was described that the second and third metal patterns 412b and 412c constituting the pad 430b and the fuse 430c are formed to have a single-layered structure of aluminum, it can be appreciated that they can be formed to have a multi-layered structure containing aluminum. For example, as shown in FIGS. 8A and 9A, the second and third metal patterns 412b and 412c may be formed to have a bilayered structure of a titanium-based metal such as titanium or titanium nitride and aluminum or a trilayered structure of a titanium-based metal, aluminum and a titanium-based metal.

Further, while not shown in drawings, the second and third metal patterns 412b and 412c may be formed to have a five-layered structure in which an aluminum layer is interposed between stacks of a titanium nitride layer and a titanium layer, or a multi-layered structure where various layers containing aluminum can be combined in a variety of ways.

Referring to FIG. 7D, a third insulation layer 414 is formed on the second insulation layer 408 including the second metal line 412a of the main cell, the second metal pattern 412b of the pad part, and the third metal pattern 412c of the fuse part. A fourth insulation layer 416 is then formed on the third insulation layer 414 and a third metal line 418 including via contacts is formed in the third and fourth insulation layers 414 and 416 of the main cell through a damascene process using copper. A fifth insulation layer 420 is then finally formed on the fourth insulation layer 416 including the third metal line 418.

Thereafter, as shown in the drawing, by repair-etching the fifth, fourth, and third insulation layers 420, 416 and 414, the second metal pattern 412b of the pad part and the third metal pattern 412c of the fuse part are exposed.

At this time, since the third metal pattern 412c of the fuse part is positioned higher than the center portion of the second metal pattern 412b of the pad part, the third metal pattern 412c of the fuse part is exposed first and the second metal pattern 412b of the pad part is subsequently exposed through transient etching when conducting the repair etching process.

Accordingly, in the present invention, the pad can be opened stably without a loss in thickness of the second metal pattern made of aluminum while the thickness of the fuse made of aluminum can be maximally reduced. As a result, in the present invention, the bondability of the pad is secured and the laser cutting of the fuse can be easily performed, whereby the reliability of the semiconductor device is improved.

Where the second and third metal patterns constituting the pad and the fuse are formed to have a bilayered structure of a titanium-based metal and aluminum or a trilayered structure of a titanium-based metal, aluminum and a titanium-based metal, the repair etching process is conducted such that the aluminum of the fuse part remains at a reduced thickness. Alternatively, as shown in FIGS. 8B and 9B, the aluminum and the titanium-based metal formed on the upper portion of the aluminum are removed to leave only the titanium-based metal formed under the aluminum remaining. In this case, the laser cutting of the fuse can be further easily performed in a subsequent repair process.

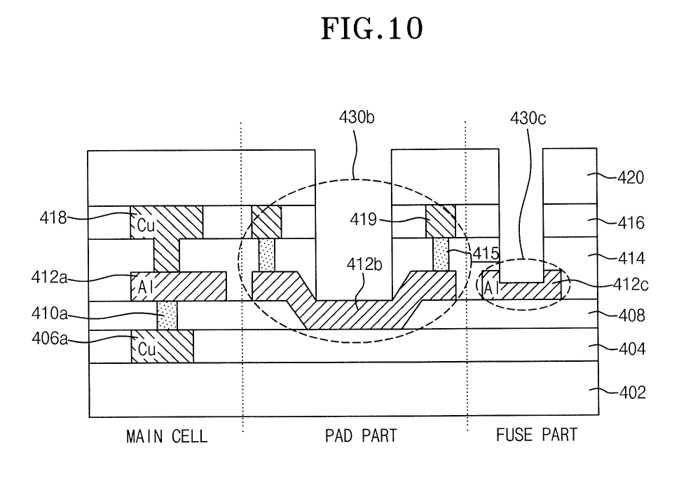

FIG. 10 is a sectional view showing a semiconductor device in accordance with still a further embodiment of the present invention.

Referring to FIG. 10, a semiconductor device according to the present embodiment has a pad 430b formed in a manner such that a first metal pattern 419 having the sectional shape of a picture frame is formed over a second metal pattern 412b having a longitudinal sectional shape which has a raised peripheral portion and a lowered center portion. That is to say, in the semiconductor device according to the present embodiment, the pad 430b of a pad part includes the second metal pattern 412b made of aluminum and having the longitudinal sectional shape which has the raised peripheral portion and the lowered center portion, second contact plugs 415 formed on the peripheral portion of the second metal pattern 412b, and the first metal pattern 419 formed of copper to contact the second contact plugs 415.

More specifically, a portion of a second insulation layer 408 in the pad part is removed. The second metal pattern 412b is formed in the removed portion of the second insulation layer 408 and on a portion of the second insulation layer 408 which is adjacent to the removed portion, to have the longitudinal sectional shape which has the raised peripheral portion and the lowered center portion. The second contact plugs 415 are formed in a third insulation layer 414 to contact the peripheral portion of the second metal pattern 412b. The first metal pattern 419 is formed on the third insulation layer 414 to have the sectional shape of a picture frame and to contact the second contact plugs 415.

Meanwhile, in the semiconductor device according to the present embodiment, a fuse 430c of a fuse part is composed of a third metal pattern 412c formed in the shape of a flat plate on the second insulation layer 408 adjacent to the pad part. The third metal pattern 412c is formed simultaneously with the second metal pattern 412b of the pad part from a metal used at the level upon which the second metal pattern 412b is formed, i.e., aluminum. In particular, the third metal pattern 412c is formed in a position higher than the center portion of the second metal pattern 412b.

Hereafter, a method for manufacturing this semiconductor device will be described.

An interlayer dielectric 402 is formed on the entire surface of a semiconductor substrate (not shown) which is divided into a main cell, a pad part, and a fuse part. After forming a first insulation layer 404 on the interlayer dielectric 402, a first metal line 406a is formed in the first insulation layer 404 of the main cell according to a well-known damascene process using copper.

After forming a second insulation layer 408 on the first insulation layer 404 including the first metal line 406a, contact holes C1 are defined to expose the first metal line 406a of the main cell, by etching the second insulation layer 408. At the same time, a portion of the second insulation layer 408 in the pad part is removed.

First contact plugs 410a are formed to contact the first metal line 406a, by filling a conductive layer in the contact holes C1. Aluminum is deposited in the removed portion of the second insulation layer 408 and on the second insulation layer 408 including the first contact plugs 410a. Through patterning the aluminum, a second metal line 412a is formed in the main cell to contact the first contact plugs 410a, a second metal pattern 412b is formed in the pad part, and a third metal pattern 412c is formed in the fuse part. The second metal pattern 412b has a longitudinal sectional shape having a raised peripheral portion and a lowered center portion due to the removal of the portion of the second insulation layer 408 in the pad part. As a result, the center portion of the second metal pattern 412b of the pad part is positioned lower than the third metal pattern 412c of the fuse part. In the same manner as described above, the second and third metal patterns 412b and 412c can be formed to have a single-layered structure of aluminum or a multi-layered structure containing aluminum.

A third insulation layer 414 is formed on the second insulation layer 408 including the second metal line 412a of the main cell, the second metal pattern 412b of the pad part and the third metal pattern 412c of the fuse part. After defining contact holes to expose the peripheral portion of the second metal pattern 412b, by etching the third insulation layer 414, second contact plugs 415 are formed to contact the peripheral portion of the second metal pattern 412b, by filling a conductive layer in the contact holes. After forming a fourth insulation layer 416 on the third insulation layer 414 including the second contact plugs 415, a third metal line 418 including via contacts is formed in the third and fourth insulation layers 414 and 416 of the main cell through a damascene process using copper. At the same time, a first metal pattern 419 having the sectional shape of a picture frame is formed in the fourth insulation layer 416 of the pad part, and through this, a pad 430b is completely formed in a manner such that the first metal pattern 419 is formed over the second metal pattern 412b. A fifth insulation layer 420 is then formed on the fourth insulation layer 416 including the third metal line 418 and the first metal pattern 419.

Thereafter, as shown in FIG. 10, by repair-etching the fifth, fourth, and third insulation layers 420, 416 and 414, the second metal pattern 412b of the pad part and the third metal pattern 412c of the fuse part are exposed.

Even in the semiconductor device according to the present embodiment, the same effects as those of the aforementioned embodiments are accomplished.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device comprising:
a pad and a fuse which are formed using a metal of the same level, wherein a center portion of the pad is positioned lower than the fuse.

2. The semiconductor device according to claim 1, wherein the pad and the fuse are formed of aluminum and have a single-layered structure.

3. The semiconductor device according to claim 1, wherein the pad and the fuse include an aluminum layer and have a multi-layered structure.

4. The semiconductor device according to claim 1, wherein the pad and the fuse have a structure in which an aluminum layer is interposed between titanium-based metal layers.

5. The semiconductor device according to claim 1, wherein the fuse has a flat planar shape.

6. A semiconductor device comprising:
a first insulation layer;
a first metal pattern formed in the first insulation layer and having a center portion that is removed and filled with the first insulation layer;
a second insulation layer formed on the first metal pattern and the first insulation layer, wherein a portion of the second insulation layer is partially removed on a portion of the first insulation layer that fills the center portion of the first metal pattern;
contact plugs formed in the second insulation layer on the first metal pattern;
a second metal pattern formed on the contact plugs and in the partially removed portion of the second insulation layer to form a pad in conjunction with the first metal pattern and the contact plugs, and the second metal pattern having a longitudinal sectional shape having a raised peripheral portion and a lowered center portion; and
a fuse composed of a third metal pattern formed on the second insulation layer separately from the pad positioned above the lowered center portion of the second metal pattern.

7. The semiconductor device according to claim 6, wherein a recess is formed in a surface of the first insulation layer that fills the center portion of the first metal pattern.

8. The semiconductor device according to claim 7, wherein the recess formed in the surface of the first insulation layer is recessed by a depth in a range of 200˜1,000Å.

9. The semiconductor device according to claim 6, wherein the first metal pattern is formed of copper.

10. The semiconductor device according to claim 6, wherein the second and third metal patterns have are formed to have a single-layered structure of aluminum.

11. The semiconductor device according to claim 6, wherein the second and third metal patterns are formed to have a multi-layered structure containing aluminum.

12. The semiconductor device according to claim 6, wherein the second and third metal patterns have a structure in which an aluminum layer is interposed between titanium-based metal layers.

13. The semiconductor device according to claim 6, wherein the fuse has a flat planar shape.

14. A semiconductor device comprising:
a first insulation layer;
a second insulation layer formed on the first insulation layer, wherein a portion of the second insulation layer is removed;
a second metal pattern formed in the removed portion of the second insulation layer and on a portion of the second insulation layer adjacent to the removed portion, and having a longitudinal sectional shape which has a raised peripheral portion and a lowered center portion;
a fuse composed of a third metal pattern formed on the second insulation layer separately from the second metal pattern to be positioned higher than the center portion of the second metal pattern;
a third insulation layer formed on the second insulation layer including the second metal pattern and the fuse;
contact plugs formed in the third insulation layer to contact the peripheral portion of the second metal pattern; and
a first metal pattern formed on the third insulation layer including the contact plugs to form a pad in conjunction with the second metal pattern and the contact plugs, wherein a center portion of the first metal pattern is removed.

15. The semiconductor device according to claim 14, wherein the second and third metal patterns are formed to have a single-layered structure of aluminum or a multi-layered structure containing aluminum.

16. The semiconductor device according to claim 14, wherein the first metal pattern is formed of copper.

17. A method for manufacturing a semiconductor device, comprising the step of:
forming a pad and a fuse using a metal of the same level,
wherein a center portion of the pad is formed to have a position lower than the fuse.

18. The method according to claim 17, wherein the pad and the fuse are formed of aluminum and have a single-layered structure.

19. The method according to claim 17, wherein the pad and the fuse are formed of aluminum and have a multi-layered structure.

20. The method according to claim 17, wherein the pad and the fuse are formed having a structure in which an aluminum layer is interposed between titanium-based metal layers.

21. The method according to claim 17, wherein the fuse is formed having a flat planar shape.

22. A method for manufacturing a semiconductor device, comprising the steps of:
forming an interlayer dielectric on a semiconductor substrate including a pad part and a fuse part;
forming a first insulation layer on the interlayer dielectric;
forming a first metal pattern in the first insulation layer of the pad part and removing and filling a center portion of the first metal pattern with the first insulation layer;
forming a second insulation layer on the first metal pattern and the first insulation layer;
etching the second insulation layer and removing a portion of the second insulation layer that is formed on the first insulation layer that fills the center portion of the first metal pattern and defining contact holes to expose the first metal pattern;
forming contact plugs in the contact holes;
forming a second metal pattern on the contact plugs of the pad part and in the removed portion of the second insulation layer such that the second metal pattern has a longitudinal sectional shape having a raised peripheral portion and a lowered center portion to constitute a pad composed of the first metal pattern, the contact plugs, and the second metal pattern;
forming a fuse composed of a third metal pattern on the second insulation layer of the fuse part and the fuse being formed at a position above the center portion of the second metal pattern; and
forming a third insulation layer on the second insulation layer to cover the pad and the fuse.

23. The method according to claim 22, wherein the first metal pattern is formed of copper.

24. The method according to claim 22, wherein, after the step of etching and removing the portion of the second insulation layer that is formed on the first insulation layer filled in the center portion of the first metal pattern, the method further comprises the step of:
recessing a portion of the first insulation layer that fills the center portion of the first metal pattern.

25. The method according to claim 24, wherein the portion of the first insulation layer is recessed by a depth in a range of 200˜1,000Å.

26. The method according to claim 22, wherein the second and third metal patterns are formed of aluminum and have a single-layered structure.

27. The method according to claim 22, wherein the second and third metal patterns are formed of aluminum and have a multi-layered structure.

28. The method according to claim 22, wherein the second and third metal patterns are formed having a structure in which an aluminum layer is interposed between titanium-based metal layers.

29. The method according to claim 22, wherein the fuse is formed having a flat planar shape.

30. A method for manufacturing a semiconductor device, comprising the steps of:
forming an interlayer dielectric on a semiconductor substrate including a pad part and a fuse part;
forming a first insulation layer on the interlayer dielectric;
forming a second insulation layer on the first insulation layer;
removing a portion of the second insulation layer in the pad part;
forming a second metal pattern in the removed portion of the second insulation layer and on a portion of the second insulation layer adjacent to the removed portion to have a longitudinal sectional shape which has a raised peripheral portion and a lowered center portion, and at the same time, forming a fuse, composed of a third metal pattern, on the second insulation layer in the fuse part to be positioned higher than the center portion of the second metal pattern;
forming a third insulation layer on the second insulation layer to cover the second metal pattern and the fuse;
forming contact plugs in the third insulation layer on the peripheral portion of the second metal pattern; and
forming a first metal pattern on the third insulation layer including the contact plugs to form a pad in conjunction with the second metal pattern and the contact plugs, wherein a center portion of the first metal pattern is removed.

31. The method according to claim 30, wherein the second and third metal patterns are formed to have a single-layered structure of aluminum or a multi-layered structure containing aluminum.

32. The method according to claim 30, wherein the first metal pattern is formed of copper.

33. The method according to claim 30, wherein the fuse is formed having a flat planar shape.
